(19) United States
(12) Patent Application Publication
(10) Pub. No.: US 2026/0066150 A1
(43) Pub. Date: Mar. 5, 2026

(54) MODULAR WIRE HARNESS ASSEMBLY FOR COOLING SYSTEM

(71) Applicant: Vertiv Corporation, Westerville, OH (US)

(72) Inventors: Isaac Shawn Harley, Delaware, OH (US); Obadiah Michael Kurtz, Delaware, OH (US); Jeffery Ronald Weaver, Westerville, OH (US)

(21) Appl. No.: 18/821,104

(22) Filed: Aug. 30, 2024

(51) Int. Cl. H01B 7/00; H05K 7/20

(52) U.S. Cl. CPC H01B 7/0045; H05K 7/20827; H05K 7/20836

(57) ABSTRACT

A cooling system having a modular wire harness assembly is disclosed. The cooling system includes: a cabinet having at least one compartment defined by a frame; a first electronic device configured to detect sensing data inside the cabinet; a second electronic device communicating with the first electronic device; and a wire harness assembly connecting the first and second electronic devices. The wire harness assembly includes a first wire harness and a second wire harness. Each of the first and second wire harnesses includes a connecting terminal at each end, the connecting terminal configured to decouplably mate with one another.

### TECHNICAL FIELD

The present disclosure relates to a cooling system, more specifically, to a high-density liquid cooling system having a modular wire harness assembly for electronic devices.

### BACKGROUND

Various techniques are being used to cool electronic devices (e.g., processors, memories, networking devices, and other heat-generating devices) that are located on a server or network rack tray in a data center. For instance, forced convection may be created by providing a cooling airflow over the devices. Fans located near the devices, fans located in computer server rooms, and/or fans located in ductwork in fluid communication with the air surrounding the electronic devices, may force the cooling airflow over the tray containing the devices.

FIG. 1 shows a typical cooling system 100 for a building, e.g., a data center 102 having an indoor unit 102 and an outdoor unit 106 as a split air conditioning system. The indoor unit 104 includes an evaporator, a fan, a compressor, and an expansion valve, while the outdoor unit 106 includes a condenser coil, a fan, and a pump. The indoor unit 104 inside the building (e.g., data center 102) fluidly communicates with the outdoor unit 106 located outside the building through a closed refrigeration circuit. FIG. 2 shows one example of an indoor unit 200 formed of a cabinet or frame 210 having one or more compartments where the evaporator and a fan 240 are in a first compartment 220 and the compressor is in an enclosed second compartment 230. The refrigerant flowing within the circuit is generally formulated to undergo phase changes within the normal operating temperatures and pressures of the system 100 so that quantities of heat can be exchanged by virtue of the latent heat of vaporization of the refrigerant. As such, the refrigerant flowing within the system 100 travels through multiple conduits and components of the circuit.

Current cooling systems often experience various failures including a failure in refrigerant coils within the refrigerant flow loop due to, e.g., moisture occurring inside the cooling unit (e.g., indoor unit 102). This may take the form of condenser or evaporator coil failures. Such a failure can lead to failures in other components in the first compartment and wiring of the cooling system. Wiring or cabling is the groundwork for a high-performance high-functioning data center. If the wiring system experiences a failure, the data center may be at risk as well. Failure of one of the electronics or the wiring can result in a serious situation such as damaging servers due to not enough cooling as it does not accurately detect the current condition inside the refrigeration unit. Therefore, it is important to detect the failure and service it accordingly.

In addition, any fault in a wire harness, which is typically comprised of: wire or cable; connectors or couplings (having mechanical, soldered, or crimped joints); cell-to-cell connections; fuses and their holders; and/or contactors, can cause relatively large resistance in an otherwise low resistance path which can result in large and undesirable amounts of heat being generated within a small area of the cooling unit. Early detection and response to such a fault in the wire harness would be highly desirable.

Serviceability is thus a major requirement for electronic devices such as sensors as well as a wire harness. However, the current wire harness is installed as one long wire piece connecting electronic devices. Thus, when there is a failure caused in the wiring system, the entire wire harness assembly needs to be replaced. Depending on the service required for the wiring harness, this could result in undesirable system downtime, which could result in data center servers failing due to improper cooling.

In view of the foregoing, there needs a solution for detecting and replacing only a necessary section of the wire harness installed in a cooling system. Further, there needs a solution for reducing a downtime downtime due to electrical or mechanical failures.

### SUMMARY

Embodiments described herein relate to techniques for cooling data centers. In particular, systems and methods of the present disclosure provide new and novel mechanisms that allow servicing a portion of wire harness assemblies without removing the entire wire assemblies. This can save unnecessary labor time and cost in the case of wire failures and further reduce downtime that would otherwise be required to service the entire wire system.

Various embodiments described herein enable a simple and efficient way for customers to adopt the system with existing infrastructure. In accordance with an embodiment of the present disclosure, a cooling system is disclosed. The cooling system can include: a cabinet having at least one compartment defined by a frame; a first electronic device detecting sensing data inside the cabinet; a second electronic device communicating with the first electronic device; and a wire harness assembly connecting the first and second electronic devices. The wire harness assembly includes a first wire harness and a second wire harness. Each of the first and second wire harnesses includes a connecting terminal at each end, the connecting terminal decouplably mating with one another. An evaporator and a compressor are disposed in the cabinet, and the frame comprises one or more openings through the wire harness assembly extends.

In some embodiments, the frame can include one or more openings through the wire harness assembly extends, and the first wire harness has a length different from the second wire harness. In some embodiments, the wire harness assembly can further include a third wire harness and a fourth wire harness configured to decouplably connected to each other, and further connected to the first and second wire harness as one wire harness.

In some embodiments, the first and third wire harnesses are base section wire harnesses, and the second and fourth wire harnesses are electronic device section wire harnesses connected to one of the first and second electronic devices. Each end of an electronic device section wire harness is configured to be connected to a base section wire harness. Each of the first and third wire harnesses includes two ends each having a first connecting terminal. In some embodiments, each of the second and fourth wire harnesses includes: an electronic device connecting end having the first connecting terminal; and a pair of base wire connecting ends, each having a second connecting terminal. The first connecting terminal and the second connecting terminal are configured to couple to each other.

In accordance with another embodiment of the present disclosure, a modular wire harness assembly is disclosed. The assembly can include a plurality of wire harnesses decouplably connected to each other, and the plurality of wire harnesses has a connecting terminal at each end. The wire harness assembly can connect a sensor to a controller for communication. In some embodiments, the plurality of wire harnesses includes: a first wire harness to which the sensor is decouplably connected; a second wire harness, to which the sensor is detachably connected, configured to be decouplably connected to the first wire harness; a third wire harness configured to be decouplably and selectively connected to the first wire harness or the second wire harness; and a fourth wire harness, to which the controller is detachably connected, configured to be decouplably connected to the third wire harness.

In some embodiments, the first and third wire harnesses are base section wire harnesses, and the second and fourth wire harnesses are electronic device section wire harnesses connected to the sensor. Each end of an electronic device section wire harness is configured to be connected to a base section wire harness. In some embodiments, each of the first and third wire harnesses includes two ends having first and second connecting terminals, respectively. Each of the second and fourth wire harnesses includes: an electronic device connecting end having the first connecting terminal, wherein the electronic device connecting end is configured to decouplably connect an electronic device thereto; and a pair of base wire connecting end, one having the first connecting terminal and another having a second connecting terminal. The first connecting terminal and the second connecting terminal are configured to couple to each other.

Other aspects and advantages of the invention will become apparent from the following detailed description, taken in conjunction with the accompanying drawings, illustrating by way of example the principles of the invention.

### BRIEF DESCRIPTION OF THE DRAWINGS

The disclosure will be readily understood by the following detailed description in conjunction with the accompanying drawings, wherein like reference numerals designate like elements:

FIG. 1 shows a perspective view of a typical cooling system for a data center according to the related art;

FIG. 2 shows a perspective view of an indoor unit of the cooling system of FIG. 1;

FIG. 3 shows a perspective view of an indoor unit enclosure of a cooling system according to one embodiment of the present disclosure;

FIG. 4 shows a schematic view of a modular harness assembly according to embodiments of the present disclosure;

FIGS. 5A and 5B show perspective and schematic views, respectively, of an electronic device section wire harness according to one embodiment of the present disclosure;

FIG. 6 shows a schematic view of a base section wire harness according to one embodiment of the present disclosure;

FIG. 7A shows a schematic view of a modular harness assembly according to one embodiment of the present disclosure, in a connected state;

FIG. 7B shows a schematic view of the modular harness assembly according to one embodiment of the present disclosure, in a disconnected state for inspection;

FIG. 8 shows a schematic view of an electronic device section wire harness according to another embodiment of the present disclosure;

FIG. 9 shows a schematic view of a base section wire harness according to another embodiment of the present disclosure;

FIG. 10A shows a schematic view of a modular harness assembly according to another embodiment of the present disclosure, in a connected state;

FIG. 10B shows a schematic view of the modular harness assembly according to another embodiment of the present disclosure, in a disconnected state for inspection;

FIG. 11 shows a partial perspective view of the indoor unit enclosure of FIG. 3 having a wire harness system according to one embodiment of the present disclosure; and

FIG. 12 shows a close-up view of FIG. 11.

### DETAILED DESCRIPTION

The figures described above and the written description of specific structures and functions below are not presented to limit the scope of what Applicant has invented or the scope of the appended claims. Rather, the Figures and written description are provided to teach any person skilled in the art to make and use the inventions for which patent protection is sought. Those skilled in the art will appreciate that not all features of a commercial embodiment of the inventions are described or shown for the sake of clarity and understanding. Persons of skill in this art will also appreciate that the development of an actual commercial embodiment incorporating aspects of the present inventions will require numerous implementation-specific decisions to achieve the developer's goal for the commercial embodiment. Such implementation-specific decisions may include and likely are not limited to, compliance with system-related, business-related, government-related, and other constraints, which may vary by specific implementation, location, and from time to time. While a developer's efforts might be complex and time-consuming in an absolute sense, such efforts would be, nevertheless, a routine undertaking for those of skill in this art having the benefit of this disclosure. It must be understood that the inventions disclosed and taught herein are susceptible to numerous and various modifications and alternative forms.

The use of a singular term, such as, but not limited to, “a,” is not intended as limiting of the number of items. The use of relational terms, such as, but not limited to, “top,” “bottom,” “left,” “right,” “upper,” “lower,” “down,” “up,” “side,” and the like are used in the written description for clarity in specific reference to the Figures and are not intended to limit the scope of the inventions or the appended claims. The terms “including” and “such as” are for illustrative purposes but not limited thereto. The terms “couple,” “coupled,” “coupling,” “coupler,” and like terms are used broadly herein and can include any method or device for securing, binding, bonding, fastening, attaching, joining, inserting therein, forming thereon or therein, communicating, or otherwise associating, for example, mechanically, magnetically, electrically, chemically, operably, directly or indirectly with intermediate elements, one or more pieces of members together and can further include without limitation integrally forming one functional member with another in a unity fashion. The coupling can occur in any direction, including rotationally. Further, all parts and components of the disclosure that are capable of being physically embodied inherently include imaginary and real characteristics regardless of whether such characteristics are expressly described herein, including but not limited to characteristics such as axes, ends, inner and outer surfaces, interior spaces, tops, bottoms, sides, boundaries, dimensions (e.g., height, length, width, thickness), mass, weight, volume, and density, among others.

The proposed systems provide a simple solution to access and replace a targeted portion of wire harness assemblies. By implementing this solution, it is possible to avoid suboptimal design changes and allow for servicing wire assemblies without disassembling or removing units in the field and replacing the entire wire assemblies. This saves work time and reduces downtime required to service the sensor in the event of a wire failure. The proposed system allows the use of existing devices with minimal reconfiguration. Additionally, the proposed system can save customers the downtime experienced when a sensor fails and enable sensor servicing to be more efficient. As a result, customers will experience both cost and time savings.

The proposed systems provide a sliding channel mechanism that can be mounted with sensors, e.g., refrigerant leak sensors. The sliding channel mechanism can be installed to slide through a frame of an indoor cooling unit and underneath a coil section inside the indoor cooling unit to place the sensors in the location that poses the highest risk of leaks. When the sensors eventually need to be replaced or undergo maintenance, a service technician can easily pull the sliding channel mechanism to reach the sensors.

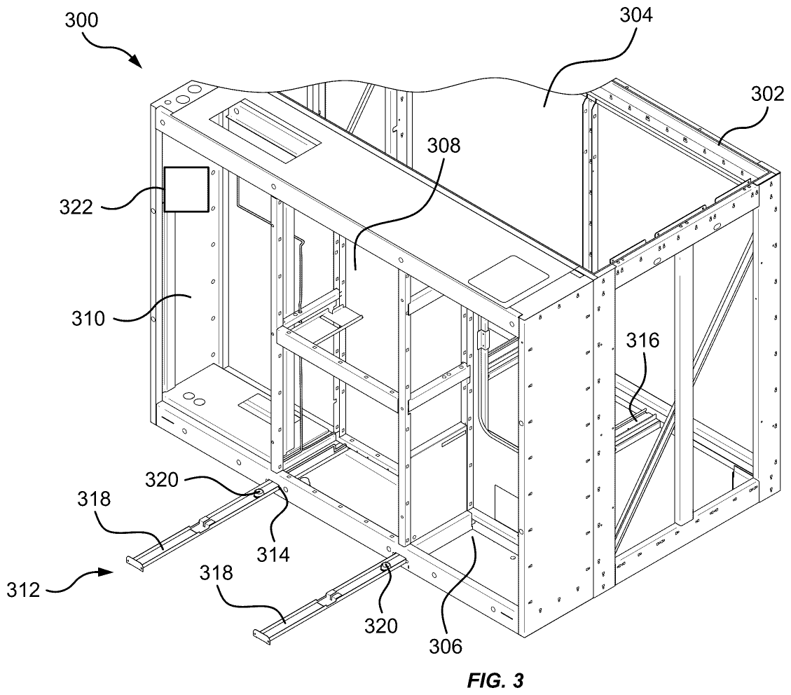

FIG. 3 shows a perspective view of an indoor unit enclosure of a cooling system 300 according to one exemplary embodiment of the present disclosure.

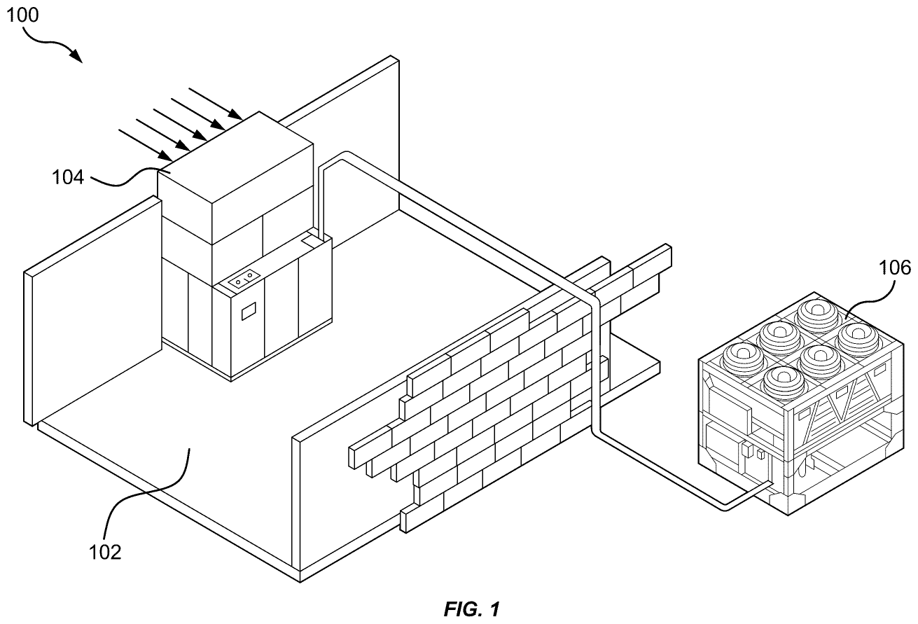

The system 300 may be used for a direct expa422nsion (DX) air conditioning unit, also called a DX unit, which cools indoor air using a condensed refrigerant liquid. As described above, a split air conditioning system (e.g., FIG. 1) puts the condenser and fans outside a building and the compressor, evaporator, and fans inside the building. The unit then pumps the refrigerant to a compressor, which compresses the gas and passes it through another heat exchanger, the condenser, outside the building. The heat that has been absorbed by the refrigerant is released to the outdoor air, and the cooled, compressed refrigerant is once again in liquid form. The unit pumps the cooled refrigerant liquid back into the evaporator and the cycle begins again. However, the system 300 is not limited to a DX unit, but any indoor cooling system can be applied for the present disclosure.

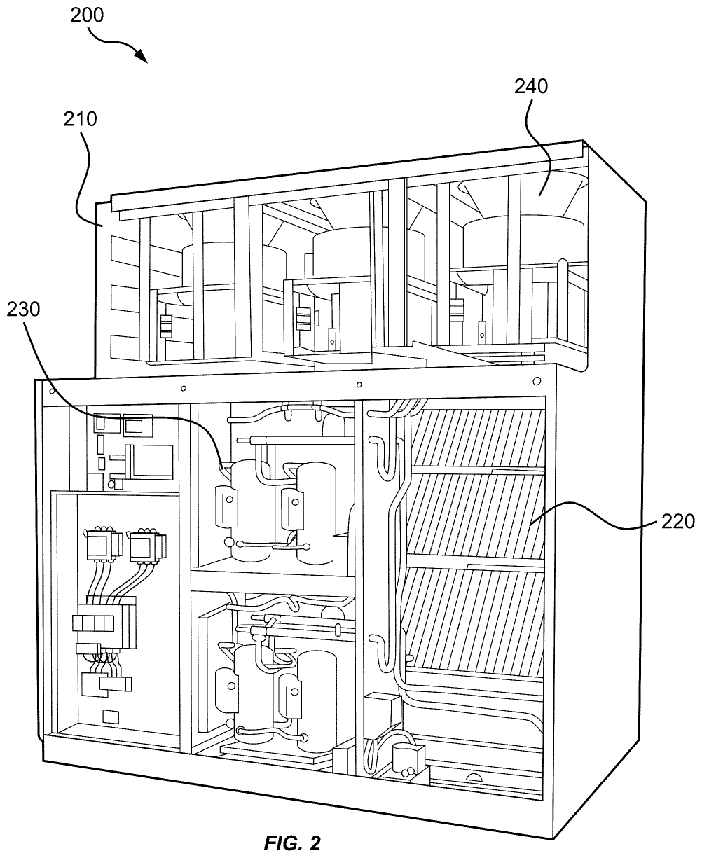

The system 300 shown in FIG. 3 may be equivalent to the frame of the indoor unit (“104” of FIG. 1 or “200” of FIG. 2). For instance, the external structure of the system 300 is a frame 302 for housing indoor units (compressor, evaporator, etc.). The frame 302 may form one or more compartment spaces. For instance, the system 300 may have a first compartment 304 in which an evaporator and a compressor are housed, and may further have second, third, and fourth compartments 306, 308, and 310. The number of compartments is not limited to what is shown in the drawings but can be anywhere from one, two, three, four, five, etc. In addition, the compartments may be completely or partially separated from each other by separation walls and windows.

In certain embodiments, the system 300 may optionally include one or more sliding mechanisms 312 to slide in and out at the lower portion of the frame 302. The system 300 may have one or more holes 314 formed on the lower portion of the frame 302, through which the one or more sliding mechanisms 312 can respectively slide. In some embodiments, each sliding mechanism 312 may include a guide rail 316 and a sliding bar 318 slidably connected with the guide rail 316.

In some embodiments, the system 300 may include one or more electronic devices or sensors 320 on the respective one or more sliding bars 318. The sensors 320 may be located toward the back side of the frame 302 to be in the first compartment 316 when the one or more sliding bars 318 are in a closed position (or first position). This configuration can accommodate the one or more sensors 320 to be positioned in the first compartment 316. However, the location of the one or more sensors 320 can vary based on the application of the system 300. The one or more sensors 320 may be installed on the frame 302 other than the sliding mechanism 312. Further, the locations of the sliding mechanisms 312 are not limited to what is shown in the drawings. The one or more sliding mechanisms 312 may be located on any other side of the indoor unit enclosure. In addition, the system 300 may not have any sliding mechanisms but the frame 302 may be rigidly configured. The one or more sliding mechanisms 312 however are optional configuration such that the system 300 may not have any sliding mechanism.

In some embodiments, the system 300 may further include a controller 322 installed inside one of the compartments 304, 306, 308, or 310. Alternatively, each compartment may have a controller installed therein, or an externally connected controller may communicate with the system 300 (e.g., sensors 320).

The controller 322 may be configured to communicate with the one or more sensors 320 by wire. When a sensing value detected by the one or more sensors 320 is outside a threshold or when there is a fault detected in the one or more sensors 320, the controller 322 may output an alarm in the form of, e.g., audio, video, haptic, etc. Additionally, the controller 322 may include a graphical user interface to visually output an alarm. In some embodiments, the controller 322 may include input buttons (touch buttons or push buttons) for a user to manipulate. Alternatively, when the sensing value is outside the threshold, the controller 322 may control the cooling system 300 to shut down.

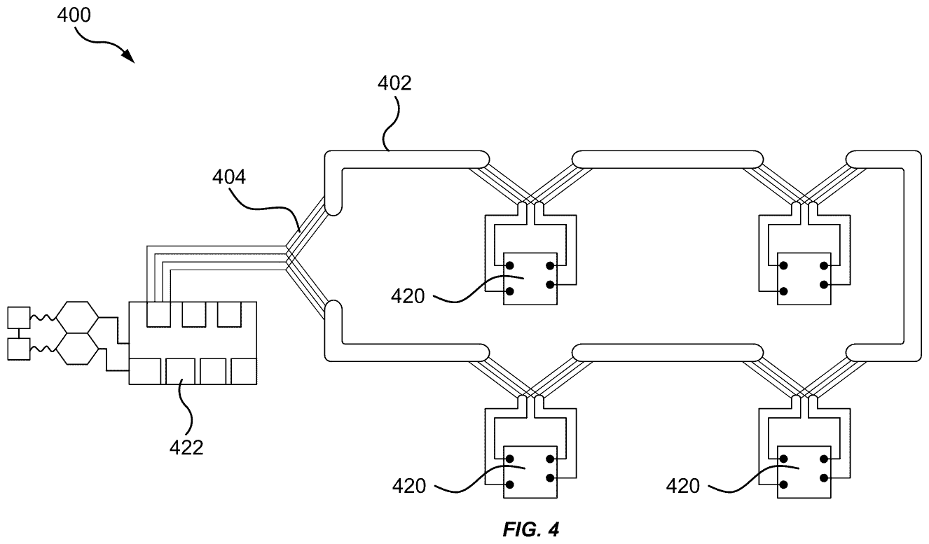

FIG. 4 shows a schematic view of a modular harness assembly 400 according to embodiments of the present disclosure. The modular harness assembly 400 may include 4, 5, 6, ... etc., number of wire harnesses 402 connected to each other. Such a number can vary based on the number of electronic devices, sizes of the system on which the modular harness assembly 400 is installed, etc. Further, the number of electronic devices, e.g., a first electronic device 420 and a second electronic device 422, may vary. In this example, there are four first electronic devices 420 and one second electronic device 422. In some embodiments, the first electronic device 420 may be a sensing unit such as a temperature sensor, a pressure sensor, a humidity sensor, or a density sensor. In certain embodiments, the first electronic device 420 may be an A2L refrigerant detection sensor.

In some embodiments, each of the wire harnesses 402 includes one or more cables 402, and includes a connecting terminal at each end which will be described later in detail. The wire harnesses 402 form one long wire harness when coupled as shown in FIG. 4 and can connect a plurality of sensors 420 to a controller 422. In addition or alternatively, the modular harness assembly 400 includes one or more base wire harnesses and one or more electronic device wire harnesses, as described hereinafter.

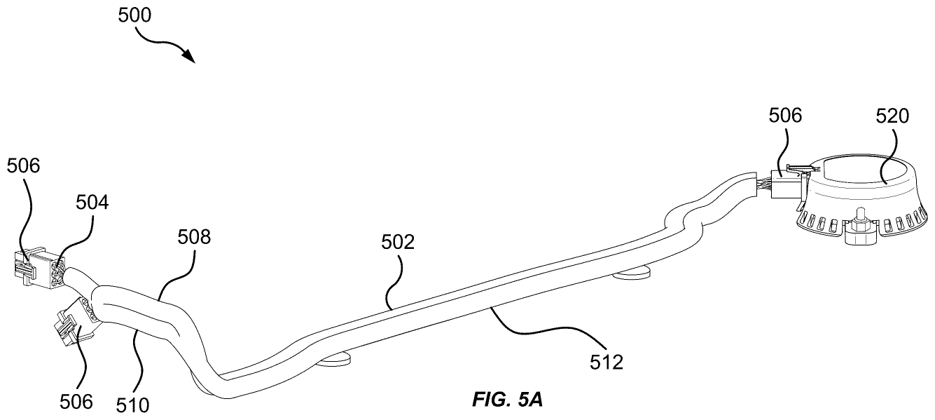

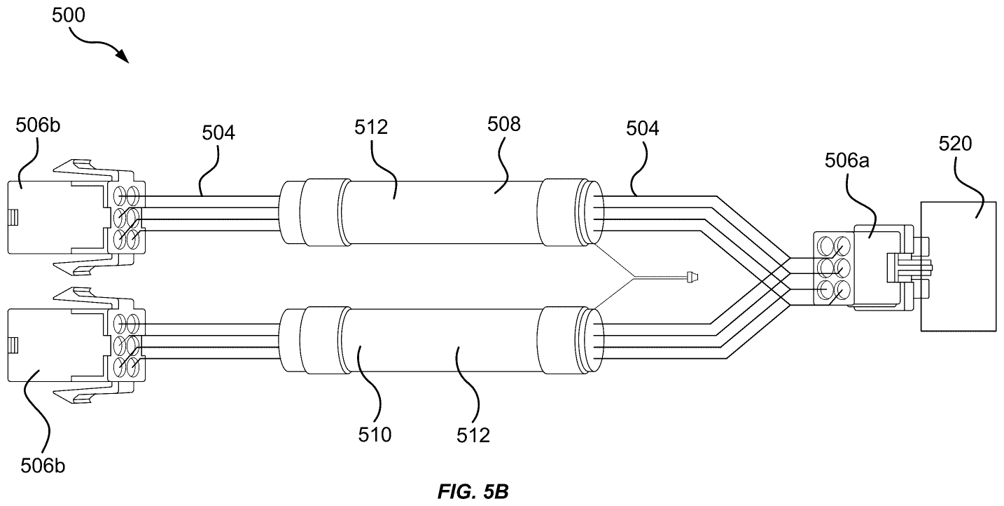

FIGS. 5A and 5B show perspective and schematic views, respectively, of an electronic device section wire harness system 500 according to one embodiment of the present disclosure. The electronic device section wire harness system 500 can include a wire harness 502 having one or more cables 504, similar to the wire harnesses 402 described above. The number of cables can vary based on the connected electronic devices or the system. Each end of the one or more cables 504 is connected to a connecting terminal 506, and each connecting terminal 506 may be similar to or different from each other, e.g., the shape, material, size, etc. The connecting terminals 506 allow coupling one wire harness 502 to another wire harness 502 or an electronic device 520.

In some embodiments, the wire harness 502 may be branched into two sets of wires, for example, a first set of wires 508 and a second set of wires 510. This configuration allows one electronic device (e.g., sensor) 520 to be connected to one connecting terminal while the branched wires can be connected to other wire harnesses to form a longer wire harness. Alternatively, the wire harness 502 may be one extended wire set or may be branched into three or more sets of wires. The one or more cables 504 may be covered by a flexible wire tubing 512. The wire tubing 512 may be made an insulation Polyvinyl Chloride (PVC) tubing configured of a flexible material while being capable of protecting the one or more cables 504. However, it is not limited to PVC tubing such that any flexible insulation material can be used for the wire tubing 512.

In some embodiments, the length of the wire harness 502 can vary based on the application. For instance, based the distance between two electronic devices to be connected, the length of the wire harness 502 can vary, or as will be described below, one or more wire harnesses 502 can be connected, as also described above.

As shown in FIG. 5B, the electronic device section wire harness system 500 may have different connecting terminals at each end. One end connected to the sensor 520 may have a first connecting terminal 506a, while two ends that branch out from the one end may each have a second connecting terminal 506b. The first connecting terminal 506a may be a male connector having, e.g., plug, pin, or prong, and the second connecting terminal 506b may be a female connector receiving the male connector for coupling. In this example, the electronic device for sensor 520 may have a female connector configuration so that the male connector 506a of the wire harness 502 can fit therein.

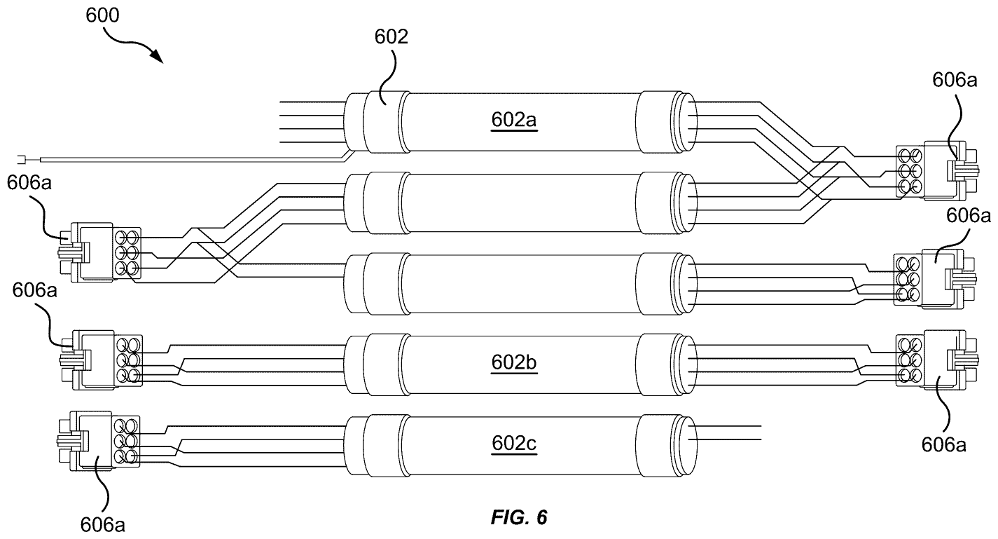

FIG. 6 shows a schematic view of a base section wire harness system 600 according to one embodiment of the present disclosure. As shown in FIG. 6, the base section wire harness system 600 may include one or more wire harnesses 602 having different wiring design. For example, the base section wire harness system 600 can include a first wire harness 602a having wires branched out at each end connected to a connecting terminal, forming a zigzag shape, while second and third wire harnesses 602b and 602c have one elongated wire configuration. The configurations of the base section wire harness system 600 are however not limited to what is shown in FIG. 6 such that wiring design can vary as necessary.

In addition, the third wire harness 602c may have only one connecting terminal. As shown, each connecting terminal of the base section wire harness system 600 is a first connecting terminal 606a, which corresponds to the first connecting terminal 506a of the electronic device section wire harness system 500. Accordingly, the first connecting terminals 606a can be respectively coupled with the second terminals 506b of the electronic device section wire harness system 500.

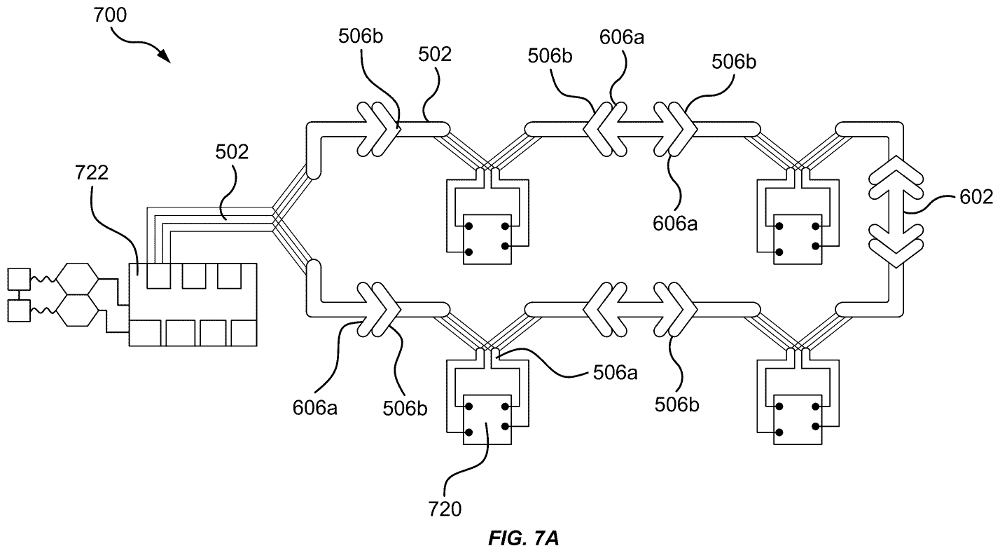

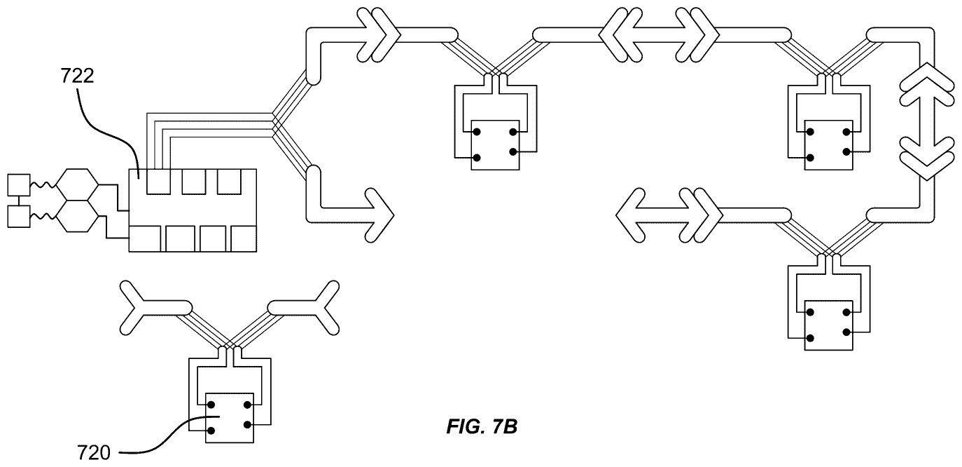

FIG. 7A shows a schematic view of a modular harness assembly 700 in a connected state, and FIG. 7B shows a schematic view of the modular harness assembly 700 in a disconnected state for inspection, according to one embodiment of the present disclosure,.

The schematic of FIG. 7A is similar to that of FIG. 4, but FIG. 7A further illustrates connecting terminals in detail. With reference to FIGS. 5B and 6, each of the wire harnesses 502 of the electronic device section wire harness system 500 has one first connecting terminal 506a coupling an electronic device 720 and a pair of second connecting terminals 506b coupling to adjacent more wire harnesses 602 of the base section wire harness system 600. The adjacent wire harnesses 602 have first connecting terminal 606a at both ends thus coupling with the second connecting terminals 506b. As described above, the first connecting terminals 506a, 606a may be male connectors while the second connecting terminals 506b may be female connectors.

Referring to FIG. 7B, any one wire harness among the modular harness assembly 700 can be manually decoupled by an operator when needed. Such that, when there is a service required in the modular harness assembly 700, rather than disconnecting and removing the entire harness installed in a system (e.g., cooling system), the modular harness assembly 700 can be sectionally removed for inspection.

For instance, when a controller (e.g., controller 322, 422, or 722) connected in the modular harness assembly 700 detects a fault reading from one or more sensors (e.g., sensors 320, 420, 520, or 720) connected in the modular wire harness assembly 700, the cooling system may be automatically or manually turned off such that a user or operate diagnoses the modular wire harness assembly 700 or any of the electronic devices to locate the fault. In particular, if there is no signal or a wrong signal reading between one or more sensors and the controller, the operator can remove the electronic devices by simply decoupling from the modular wire harness assembly 1100 to inspect without interrupting the signal communication between undefeated electronic devices.

In a case in which the wire harness assembly 700 is defective, the entire signal communication may not work. In this case, the cooling system may be automatically turned off or the operator can manually turn off the cooling system to inspect the modular wire harness assembly 700. Unlike the typical wire harness, the modular wire harness assembly 700 according to the present disclosure can be sectionally removed as shown in FIG. 7B for inspection and repair. This allows the operator to replace only the defective wire harness without having to replace the entire wire harness assembly.

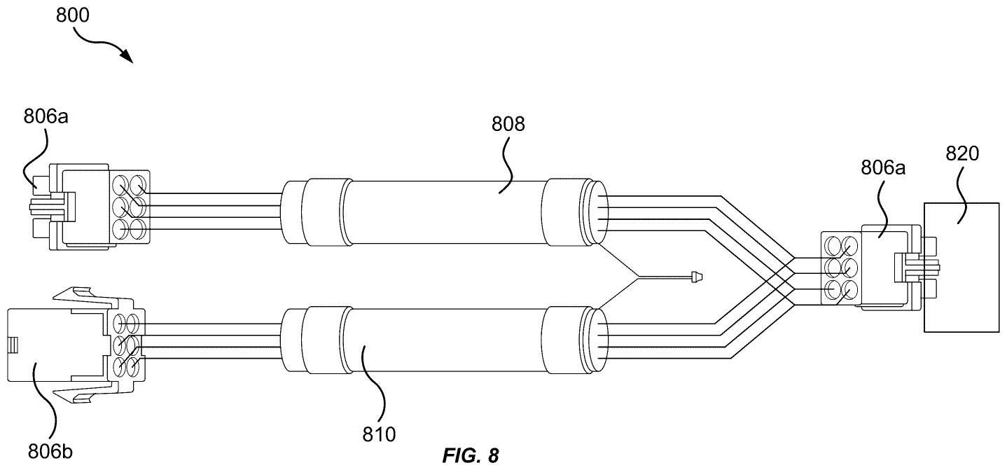

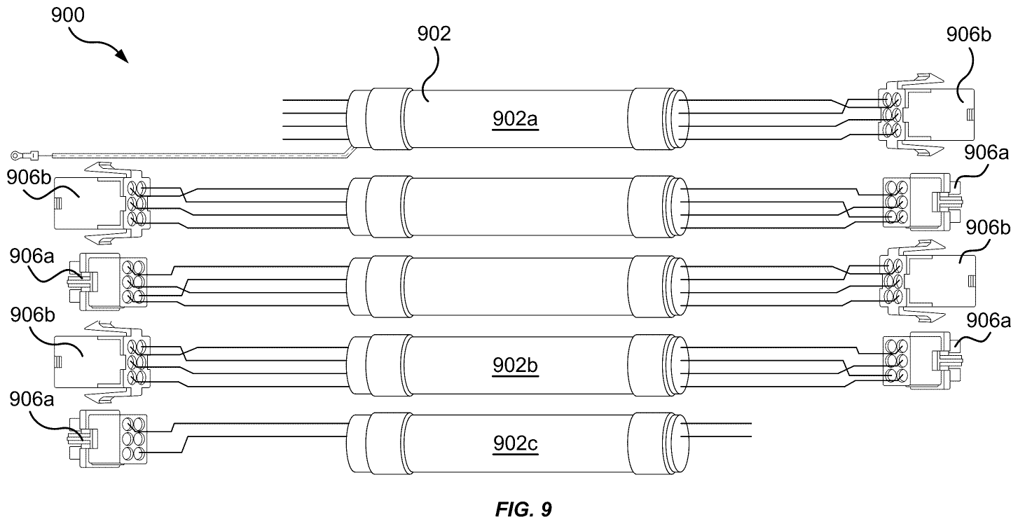

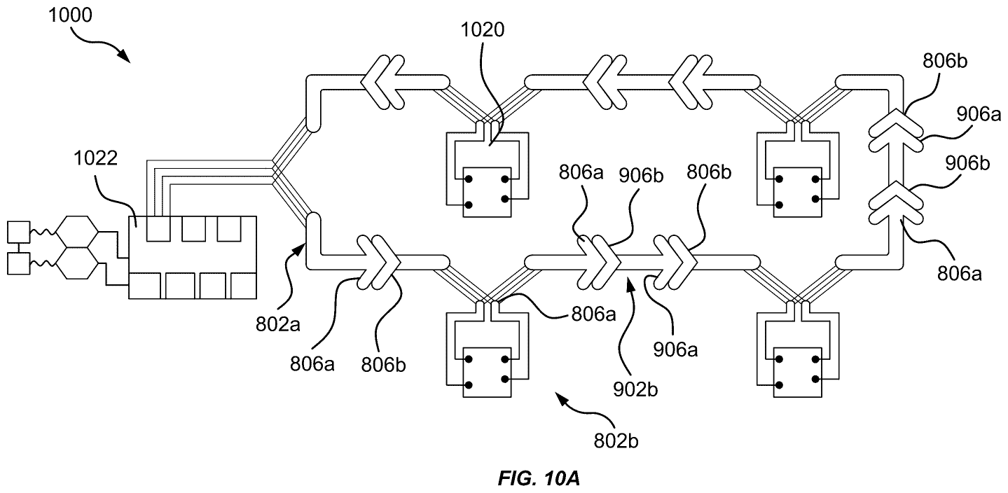

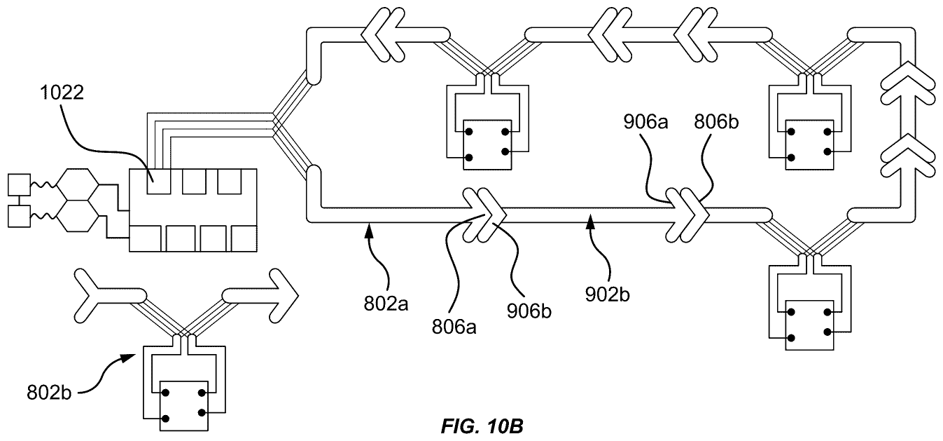

FIGS. 8-10B describe a modular wire harness system according to another embodiment of the present disclosure. More specifically, FIG. 8 shows a schematic view of an electronic device section wire harness system 800, FIG. 9 shows a schematic view of a base section wire harness system 900, FIG. 10A shows a schematic view of a modular harness assembly 1000 in a connected state, and FIG. 10B shows a schematic view of the modular harness assembly 1000 in a disconnected state for inspection, according to another embodiment of the present disclosure.

The configurations of the modular wire harness system according to another embodiment are generally similar to those of the modular wire harness system according to one embodiment of FIGS. 5B-7B. However, referring to FIG. 8, a connecting terminal at one of the branching wires is different from other connecting terminals. That is, unlike the first set of wires 508 of the electronic device section wire harness system 500 having the second connecting terminal or female connector 506b at its end, a first set of wires 808 of the electronic device section wire harness system 800 has a a first connecting terminal or male connector 806a at its end. A second set of wires 810 has a second connecting terminal or female connector 806b similar to that of the electronic device section wire harness system 500 as well as the other end connecting to an electronic device 820.

In addition, connecting terminals of the base section wire harness system 900 are also reconfigured to have different connecting terminals rather than having the same connecting terminals as the base section wire harness system 600 (see FIG. 6). In this example, the base section wire harness system 900 has first and second connecting terminals 906a and 906b are alternatively connected to ends of the each wire harness 902. This reconfiguration may be prepared by a manufacturer. There are several advantages of alternating the connecting terminals.

Turning to FIGS. 10A and 10B, which shows the modular harness assembly 1000 that may correspond to the the modular harness assembly 400 of FIG. 4 and the modular harness assembly 700 of FIGS. 7A and 7B. However, unlike the modular harness assembly 700 having connecting terminals as shown in FIGS. 5B and 6, each end of wire harness that are connected to adjacent wire harness, e.g., wire harness 802 of the an electronic device section wire harness system 800 connected to the wire harness 902 of the base section wire harness system 900, has a different connecting terminal, either first (male) or second (female) connecting terminal. This configuration allow, when one wire harness section (e.g., 802b) is removed, as shown in FIG. 10B, the adjacent wire harnesses (e.g., 802a and 902b) that previously connected to each end of the wire harness 802a can be connected to each other, by female and male connectors. Accordingly, even if one wire harness 802b is removed for repair and inspection, the modular wire harness assembly 1000 allow the communication between the electronic devices, thus significantly reducing system downtime. Once the defective wire harness is repair, the repaired wire harness or a new wire harness can be quickly connected between, e.g., wire harness 802a and wire harness 902b, for the normal operation.

According to various embodiments, the one or more sensors (for first electronic devices) 320, 420, 520, 720, 820, 1020, or 1120 detect sensing data and transmit to the controller (or second electronic device) 322, 422, 722, or 1022. When at least one sensing data is outside a threshold, the controller controls the cooling system to turn off and enter a wire harness assembly check mode. In some embodiments, the cooling system may be automatically turned off or an operator needs to manually turn off the system. In addition, the controller may generate an output to alert the operator of the current status. The alert may be in the form of sound, visual, haptic, etc. The controller may be equipped with a display screen (e.g., touch screen) to visually display or may be equipped with LED lights to generate different color outputs (in stages) as an alarm.

As described above, the sensor may be a temperature sensor, a pressure sensor, a humidity sensor, and/or a density sensor so that the sensing data depends on the type of sensor. Alternatively, there may be more than one same type of sensor or different types of sensor.

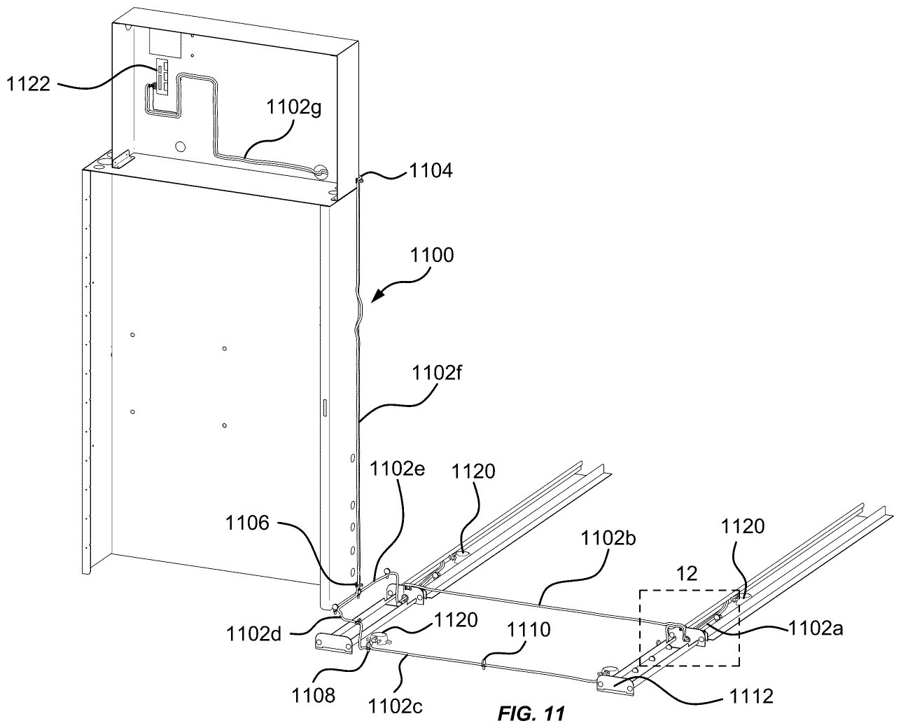

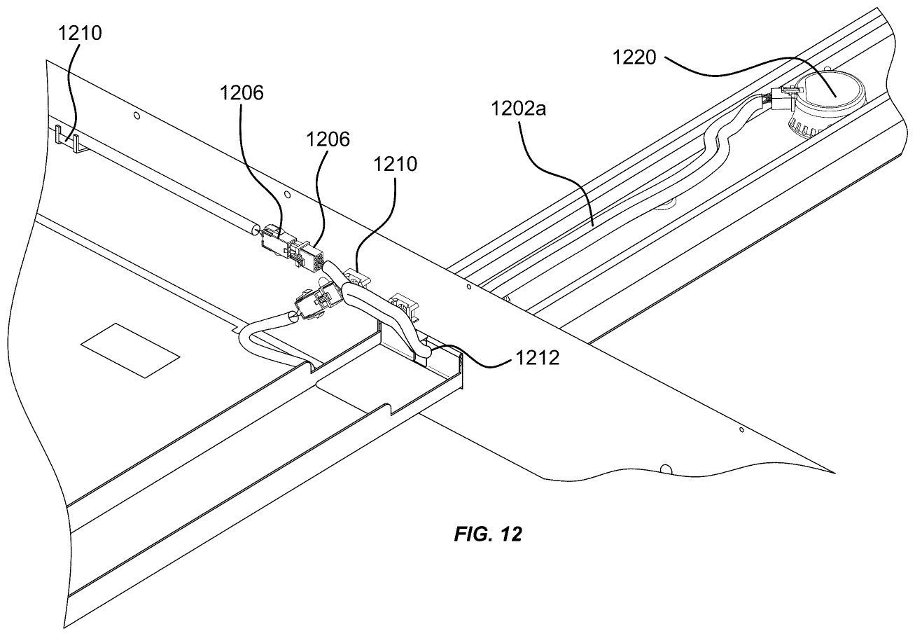

FIG. 11 shows a partial view of the system 300 of FIG. 3 having a modular wire harness assembly 1100 installed, and FIG. 12 shows a close-up view 12 of FIG. 11. The modular wire harness assembly 1100 which correspond to the modular wire harness assemblies 400, 700, and 1000. In this example, the modular wire harness assembly 1100 includes seven (7) wire harnesses 1124a-1124g; however, there may be more or less than 7 wire harnesses connected to each other to form the modular wire harness assembly 1100, based on the number and location of electronic devices (e.g., 320, 420, 520, 720, 820, 1020, or 1120), the size of the system 300, etc. In addition, the wire harnesses 1124a-1124g may have lengths different from each other. The modular wire harness assembly 1100 may be assembled to the system 300 using brackets or hooks 1104, 1106, 1108, 1110,

As described above, each of the wire harnesses 1124a-1124g includes several cables therein, either branched into two or more sets of wires or as one elongated wires, covered by flexible wire tubing. Accordingly, in a case in which the system 300 includes one or more sliding mechanism 312, as the sliding mechanisms 312 slide in and out, the modular wire harness assembly 1100 can also slide along with the sliding mechanisms 312. In some embodiments, the wire harnesses 1124a-1124g are detachable connected to each other such that a user can easily couple and decouple the corresponding connecting terminals, without any external/additional assistance. In addition, the modular wire harness assembly 1100 may be attached or coupled to the frame 302 of the system 300 (see FIG. 3) by, e.g., a tie rod or any mounting configuration that can tightly hold the modular wire harness assembly 1100 while allowing the modular wire harness assembly 1100 to bend/move when the system 300 includes the sliding mechanisms 312.

In some embodiments, referring to FIG. 12, the frame 302 may include one or more brackets 1210 to hold the modular wire harness assembly 600, and may further include one or more openings/holes 1212 through which the modular wire harness assembly 1100 extends to connect the plurality of wire harnesses 1124a-1124g.

The modular wire harness assembly 1100 or modular wire harness assemblies 400, 700, and 1000 can be implemented in any cooling system or any other system requiring wiring between electronic devices (e.g., with or without the sliding mechanisms 312). Such a modular wire harness assembly 1100 having a plurality of wire harnesses decouplably connected to each other can be useful when a fault occurs at a portion of one of the plurality of wire harnesses. Rather than replacing the entire wire harness as typically used, the present configuration makes it possible to replace only the affected wire portion, thus reducing the cost in the long run and servicing time.

As described above, one aspect of the present system is to facilitate the accessibility of electronic devices that are typically not accessible due to structural limitations and arrangements. The present disclosure recognizes the need to improve the current configuration for a user or operator to replace a section of the wire harness assembly, without replacing the entire wire harness assembly, and further reduce the downtime for unnecessary manual efforts of disassembling and assembling the entire wiring system. Moreover, even when one wire harness is removed, the other wire harnesses currently connected in the modular wire harness assembly can be connected to each other. Therefore, the present disclosure can reduce the cost and time while promoting the use or service of electronic devices more easily.

Further, the present system is designed to allow operators/technicians the ability to troubleshoot and replace certain sections of a harness quicker and easier than previously allowed. More specifically, the presently disclosed system not only makes a harness a more reliable product through its inherent design but also allows a technician the ability to remove and replace a specific portion of a harness without disrupting the other systems associated with a harness. The quick nature in which a harness can be diagnosed and a specific section can be replaced allows for quicker turnaround of the cooling system and fewer cancellations.

Moreover, refrigeration and air conditioning applications are under increased regulatory pressure to reduce the global warming potential of the refrigerants they use. Commonly used refrigerants for commercial HVAC systems include R-410A, R-407C, R-134a, etc. which are hydrofluorocarbons (HFCs) with non-flammability and low toxicity. Several refrigerants have been developed such as A2L refrigerants (e.g., R-1234yf, R-1234ze, R-452B, R-454B, R-32, etc.). However, A2L poses a combustion risk. Thus, a leak detection sensor is necessary in an enclosed indoor cooling system, for example, as shown in FIG. 3, which then further requires a wiring configuration connecting from the sensor located inside the system to a controller which may be located outside or an external portion of the system. Thus, it is necessary or indeed required for the system using A2L refrigerant to be equipped with an A2L refrigerant leak detection sensor(s) with a special wiring configuration.

Serviceability is a major requirement for A2L sensors. However, due to the installation location of an A2L refrigerant leak detection sensor, the sensor is not easily accessible. For instance, the A2L refrigerant leak detection sensor is generally located at the bottom of the indoor cooling unit as the A2L refrigerant sinks toward the bottom due to its higher density than air. In addition, the ASHRAE guidelines provide recommendations and requirements for the installation location for refrigerant leak detection sensors, and the recommended locations are often inaccessible for maintenance without disconnecting and moving the entire cooling system. Thus, a long wire harness is necessary to reach from a control system to the sensors located in not-so-easily-reachable areas inside the cooling unit. The presently described system allows, when service is needed in either a sensor or wiring, a technician to easily reach the faulty sensor or part of the modular wire harness assembly consisting of a plurality of interconnected wire harnesses, thereby being able to provide the service required for that specific sensor and/or wire.

As should now be apparent, a significant aspect of the present disclosure relates to the modular aspect of the harness. By providing a modular harness, troubleshooting is simplified and individual harness sub-assemblies may be easily removed and replaced without requiring to replace the entire harness assembly as is required with non-modular harnesses of the prior art. As a result of the interchangeability of the sub-assemblies the harness spare parts inventory required to service a particular system (e.g., cooling system for data center) can be also reduced over inventory requirements for prior art harnesses.

Each of the components and their constituent parts, and other variations described herein may include corresponding features described with reference to each of the other components and features described without limitation.

In this application, including the definitions, the term “module” or the term “controller” may be replaced with the term “circuit. ” The term “module” refers to or includes: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Peri, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

None of the elements recited in the claims are intended to be a means-plus-function element within the meaning of 35 U.S.C. § 112(f) unless an element is expressly recited using the phrase “means for,” or in the case of a method claim using the phrases “operation for” or “step for. ”

Although the terms first, second, third, etc. may be used herein to describe various elements, pumps, condenser fans, compressors, circuits, components and/or modules, these items should not be limited by these terms. These terms may be only used to distinguish one item from another item. Terms such as “first,” “second,” and other numerical terms when used herein do not imply a sequence or order unless clearly indicated by the context. Thus, a first item discussed herein could be termed a second item without departing from the teachings of the example implementations.

Process flowcharts discussed herein illustrate the operation of possible implementations of systems, methods, and computer program products according to various embodiments of the present invention. In this regard, each block in the flowchart may represent a module, segment, or portion of code, which comprises one or more executable instructions for implementing the specified logical function(s). It should also be noted that, in some alternative implementations, the functions noted in the blocks might occur out of the order depicted in the figures. For example, blocks shown in succession may be executed substantially concurrently. It will also be noted that each block of flowchart illustration can be implemented by special-purpose hardware-based systems that perform the specified functions or acts, or combinations of special purpose hardware and computer instructions.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not intended to be exhaustive or to limit the embodiments to the precise forms disclosed. It will be apparent to one of ordinary skill in the art that many modifications and variations are possible in view of the above teachings.

What is claimed is:

1. A cooling system comprising:
a cabinet comprising at least one compartment defined by a frame, wherein an evaporator and a compressor are disposed in the cabinet;
a first electronic device configured to detect sensing data inside the cabinet;
a second electronic device configured to communicate with the first electronic device; and
a wire harness assembly configured to connect the first and second electronic devices, wherein the wire harness assembly comprises a first wire harness and a second wire harness, and wherein each of the first and second wire harnesses comprises a connecting terminal at each end, the connecting terminal configured to decouplably mate with one another,
wherein the frame comprises one or more openings through the wire harness assembly extends.

2. The system of claim 1, wherein the first wire harness has a length different from the second wire harness.

3. The system of claim 1, wherein the wire harness assembly further comprises a third wire harness and a fourth wire harness configured to decouplably connected to each other, the connected third and fourth wire harnesses configured to be connected to the first and second wire harness as one wire harness assembly.

4. The system of claim 3, wherein each of the first and third wire harnesses is a base section wire harness, and each of the second and fourth wire harnesses is an electronic device section wire harness connected to at least one of the first or second electronic device, and
wherein ends of each of the electronic device section wire harnesses are configured to be connected to corresponding ends of each of the base section wire harnesses.

5. The system of claim 4, wherein each of the first and third wire harnesses includes two ends having first and second connecting terminals, respectively,
wherein each of the second and fourth wire harnesses includes:
an electronic device connecting end having the first connecting terminal; and
a pair of base wire connecting ends, one having the first connecting terminal and another having a second connecting terminal, and
wherein the first connecting terminal and the second connecting terminal are configured to couple to each other.

6. The system of claim 5, wherein the second wire harness is decouplably connected between the first and third wire harnesses, and
wherein, when the second wire harness is decoupled, the first and third wire harnesses are configured to be connected by coupling the corresponding first and second connecting terminals to each other.

7. The system of claim 5, wherein the first connecting terminal of the pair of base wire connecting ends is configured to be decouplably connected to the second connecting terminal of the base section wire harness, and
wherein the second connecting terminal of the pair of base wire connecting ends is configured to be decouplably connected to the first connecting terminal of the base section wire harness.

8. The system of claim 5, wherein the first or second electronic device is configured to be connected to the electronic device connecting end.

9. The system of claim 1, wherein the first electronic device includes at least one of a temperature sensor, a pressure sensor, a humidity sensor, or a density sensor.

10. The system of claim 1, wherein the first electronic device includes a plurality of sensors.

11. The system of claim 1, wherein the second electronic device includes a controller configured to generate an output informing the wire harness assembly check mode, and
wherein, when the sensing data is outside a threshold, the controller controls the cooling system to turn off and enter a wire harness assembly check mode.

12. The system of claim 1, wherein the cabinet comprises a sliding mechanism configured to slide in and out of the cabinet, wherein the first electronic device and the wire harness assembly are decouplably disposed on the sliding mechanism.

13. The system of claim 12, wherein the wire harness assembly is flexibly disposed on the sliding mechanism and configured to slide along with the sliding mechanism.

14. The system of claim 13, wherein the frame and the sliding mechanism comprise a plurality of connecting terminal holders on which the connecting terminals are respectively decouplably attached.

15. A modular wire harness assembly for a cooling system comprising:
a plurality of wire harnesses decouplably connected to each other, wherein the plurality of wire harnesses has a connecting terminal at each end,
wherein the wire harness assembly is configured to connect a sensor to a controller for communication.

16. The modular wire harness assembly of claim 15, wherein the plurality of wire harnesses comprises:
a first wire harness;
a second wire harness, to which the sensor is detachably connected, configured to be decouplably connected to the first wire harness;
a third wire harness configured to be decouplably and selectively connected to the first wire harness or the second wire harness; and
a fourth wire harness, to which the controller is detachably connected, configured to be decouplably connected to the third wire harness.

17. The system of claim 16, wherein the first and third wire harnesses are base section wire harnesses, and the second and fourth wire harnesses are electronic device section wire harnesses connected to the sensor, and
wherein each end of an electronic device section wire harness is configured to be connected to a base section wire harnesses.

18. The system of claim 17, wherein each of the first and third wire harnesses includes two ends having first and second connecting terminals, respectively,
wherein each of the second and fourth wire harnesses includes:
an electronic device connecting end having the first connecting terminal, wherein the electronic device connecting end is configured to decouplably connect an electronic device thereto; and
a pair of base wire connecting end, one having the first connecting terminal and another having a second connecting terminal, and
wherein the first connecting terminal and the second connecting terminal are configured to couple to each other.

19. The system of claim 18, wherein the second wire harness is decouplably connected between the first and third wire harnesses, and
wherein, when the second wire harness is decoupled, the first and third wire harnesses are configured to be connected by coupling the corresponding first and second connecting terminals to each other.

20. The modular wire harness assembly of claim 15, the connecting terminals of the plurality of wire harnesses are configured to mate one another to be configured as one elongated wire harness.
